(19) United States
(12) Patent Application Publication
(10) Pub. No.: US 2017/0327938 A1
(43) Pub. Date: Nov. 16, 2017

(54) DEVICE FOR DEPOSITING A LAYER ON A SUBSTRATE

(71) Applicant: AIXTRON SE, Herzogenrath (DE)

(72) Inventor: Michael LONG, Herzogenrath (DE)

(21) Appl. No.: 15/531,328

(22) PCT Filed: Nov. 19, 2015
(86) PCT No.: PCT/EP2015/077113

§ 371 Date: May 26, 2017

(30) Foreign Application Priority Data
Nov. 28, 2014 (DE) 10 2014 117 492.5

(51) Int. Cl. C23C 14/24; C23C 16/455

(52) U.S. Cl. CPC C23C 14/24; C23C 16/4557

(57) ABSTRACT

A device for depositing a layer on a substrate includes a process chamber and a gas inlet element. The substrate is moved in a movement direction in the process chamber during a coating process. The gas inlet element has a first, second and third gas distribution chamber with a first, second and third gas outlet zone, respectively. The second gas outlet zone is arranged immediately before the first gas outlet zone in the movement direction of the substrate and the third gas outlet zone is arranged immediately after the first gas outlet zone in the movement direction of the substrate. The first, second and the third gas distribution chambers each have a gas-heating apparatus. The first gas distribution chamber has an evaporating apparatus for a solid or liquid starting material, which can be fed into the first gas distribution chamber through an feed-in opening.

### RELATED APPLICATIONS

This application is a National Stage under 35 USC 371 of and claims priority to International Application No. PCT/EP2015/077113, filed 19 Nov. 2015, which claims the priority benefit of DE Application No. 10 2014 117 492.5, filed 28 Nov. 2014.

### FIELD OF THE INVENTION

The invention pertains to a device for depositing a layer on a substrate, which is moved in a moving direction in a process chamber transverse to the direction of extent of a gas inlet element during the coating process, wherein the gas inlet element features a first gas distribution chamber with an infeed opening for feeding in a starting material and with a first gas outlet zone, which extends over the entire width of the moving path of the substrate and points toward the substrate, for the outflow of a first gas containing the starting material, and wherein, parallel to the direction of extent of the first gas outlet zone, a second gas outlet zone of a second gas distribution chamber is arranged in front of the first gas outlet zone referred to the moving direction of the substrate for the outflow of a second gas flow and a third gas outlet zone of a third gas distribution chamber is arranged behind the first gas outlet zone referred to the moving direction of the substrate for the outflow of a third gas flow.

The invention concerns the technical field of depositing layers, particularly semiconductor layers, on a substrate. This technical field includes Chemical Vapor Deposition and Physical Vapor Deposition. In the former, a chemical reaction takes place during the deposition of a gaseous starting material introduced into a process chamber; in the latter, a change in the state of aggregation of a gaseous starting material introduced into a process chamber essentially takes place in that the gaseous starting material condenses on the substrate. The field of application of the invention particularly concerns Organic Vapor Phase Deposition (OVPD). In this deposition method, an organic starting material is supplied either in the form of a solid or a liquid. The starting material is heated to an evaporation temperature. The thusly generated vapor is transported into a process chamber of a coating device. This may be realized with the aid of a carrier gas. The substrate is in contact with a cooled susceptor such that the evaporated organic starting material condenses on the surface of the substrate. This technical field particularly also includes the manufacture of OLEDs.

### BACKGROUND

A generic device of this type is described in US 2012/0237695 A1. The “Linear Vapor Deposition System” described in this publication features a gas inlet element with multiple linear gas outlet zones that respectively extend parallel to one another, wherein the gaseous starting material flows out in the direction of the substrate through a central gas outlet zone and an inert gas flows out in the direction of the substrate through outer gas outlet zones arranged distant from the central gas outlet zone. The substrate is moved transverse to the direction of extent of the gas outlet zone.

U.S. Pat. No. 5,595,602, U.S. Pat. No. 6,037,241, U.S. Pat. No. 7,238,389 B2, U.S. Pat. No. 7,780,787 B2, WO 2012/175126, WO 2012/175128 and WO 2012/175307 describe gas inlet elements on PVD devices, which utilize an electrically heated, porous solid foam body for gasifying the solid or liquid particles in an aerosol stream by transferring evaporation heat in order to transport the gaseous starting material from a gas outlet opening of the gas inlet element to a substrate, on which the gasified starting material once again condenses, with the aid of a carrier gas.

### SUMMARY OF THE INVENTION

In contrast to gas feeding devices, in which the inflow of the gaseous starting materials to the substrate can be activated and deactivated by means of valves, the utilization of a heated foam body provides the option of influencing the material flow of the starting material to the substrate by changing the temperature of the foam body. If the temperature of the foam body lies below the evaporation temperature, an enrichment of the aerosol introduced into the foam body takes place therein. The evaporation rate is increased by raising the temperature of the evaporation body formed by the foam body such that the material flow of the starting material to the substrate can be adjusted by controlling the temperature. The utilization of porous foam bodies as a vapor source also provides the advantage of allowing the simultaneous evaporation of multiple starting materials that differ from one another, for example, in order to introduce multiple starting materials into the process chamber and to thereby deposit organic molecules, which emit light on different wavelengths, on a substrate. A doping process can also be realized in this way. The vapor essentially flows out of the foam body uniformly over its entire gas outlet surface. In this case, it is problematic that the vapor, which flows out through the edge sections of the gas outlet surface, condenses due to the lower gas temperature of the gas surrounding the gas outlet surface. This can lead to flocculations, i.e. particle formations, in the gaseous phase. The latter disadvantageously affects the quality of the deposited layer.

The invention is based on the objective of developing a device, by means of which large-surface substrates can be coated with one or more organic starting materials, wherein a high throughput should be achieved with minimal material input and without thermal destruction of the starting material.

This objective is attained with the invention specified in the claims, wherein each claim basically represents an independent solution to the above-defined objective.

It is initially and essentially proposed that three or more gas outlet zones extend directly adjacent to one another. The gaseous starting material flows into the process chamber through at least one central gas outlet zone. An inert gas flows into the process chamber through the two outer gas outlet zones flanking the central gas outlet zone. The two inert gas flows affect the edge region of the central gas flow such that the central gas flow does not diverge. The two outer gas flows effectively cause a collimation of the central gas flow transporting the starting material. The two outer gas flows therefore form collimator gas flows that impose a linear flow direction on the central gas flow. All three gas flows have an elevated temperature, wherein each of the three gas distribution chambers features a gas heating apparatus for this purpose. An evaporation of an aerosol containing solid or liquid particles furthermore takes place in the central gas distribution chamber. The evaporation apparatus of the central gas distribution chamber may be formed by the heating apparatus arranged therein. The heating apparatus or the evaporation body may consist of an electrically conductive, open-pored solid body of the type described in the initially cited prior art. It may consist of a foam body that can completely occupy the respective gas distribution chamber assigned thereto. Adjacent gas distribution chambers are separated from one another by an electrically insulating partition wall. The partition wall may consist of a ceramic material. One or more process gas distribution chambers, as well as the second and third gas distribution chambers, may be assigned to a housing that forms a gas inlet element. It consists of an elongate housing that extends over the entire width of the substrate transverse to the moving direction thereof. The process gas flow exiting the at least one process gas outlet zone is flanked by heated inert gas flows such that no cooling of the edge region of the process gas flow takes place. The above-described flocculations in the gaseous phase are thereby prevented. Since the substrate is slowly moved transverse to the direction of extent of the linearly adjacent gas outlet zones, a layer consisting of a condensate of the evaporated starting material exiting the central gas outlet zone is deposited on the surface of the substrate during its pass through the device. The substrate is cooled for this purpose. It moves over an actively cooled susceptor. Instead of moving the substrate, it would also be conceivable to move the gas inlet element relative to the substrate. End faces are respectively formed by the two lateral surfaces of the gas inlet element, which are assigned to the ends of the linear gas outlet zones. On these end faces, the heating apparatuses, i.e. particularly the foam bodies, feature electrodes, by means of which an electric current can be fed into the open-pored solid body such that the foam bodies are resistance-heated. A process gas distribution chamber may be provided. Two or more process gas distribution chambers may also be provided and arranged directly adjacent to one another. The multiple process gas distribution chambers then directly border on one another. The latter also applies to the respective gas outlet zones of the process gas distribution chambers. The at least one process gas distribution chamber may be divided into one or more sections. The sections may be separated by a plate. The plate may feature openings. An upstream section is connected to the gas inlet opening. A downstream section is assigned to the gas outlet zone. The plate affects the flow and forms a flow restriction plate or diffusor plate. The gas inlet opening of the first gas distribution chamber is connected to an aerosol generator. The aerosol generator may feature a reservoir, in which a powder or a liquid is stored. A solid or droplet aerosol is generated and fed into the gas distribution chamber with the aid of a carrier gas, wherein the aerosol evaporates in the gas distribution chamber due to the temperature acting thereupon. Since a porous solid body is utilized, the gas flow is simultaneously homogenized such that the infeed of the aerosol only has to take place at a few locations. The evaporation preferably takes place in the upstream section only. The local open-pored solid body delivers sufficient heat for evaporating the aerosol being fed in. The vapor flows into the downstream section through a separation zone such as, for example, through the openings of the flow restriction plate or separating plate. This downstream section may be actively cooled by introducing a cooled gas such that a condensation of the starting material can be realized at this location as needed. In this way, the gaseous starting material is prevented from flowing out of the gas outlet zone if it is not needed at this location. However, the downstream section is not cooled if the gaseous starting material should flow out of the gas outlet opening. The local foam body then has a temperature that lies above the evaporation temperature of the starting material such that the starting material evaporated in the upstream section can flow through the downstream section of the process gas distribution chamber and the foam body arranged therein in an unobstructed fashion. The infeed of the starting material into the process chamber can therefore be activated and deactivated with the foam body arranged in the downstream section of the process gas distribution chamber, but no loss occurs in the deactivated state because the starting material is intermediately stored in the downstream section of the gas distribution chamber and in the foam body arranged therein. It evaporates locally after being heated accordingly. The separation zone between an upstream section and a downstream section of the process gas distribution chamber does not necessarily have to feature a diffusor plate or the like. It is also conceivable that merely the boundary between two gas heating apparatuses extends in the region of the separation zone. A downstream gas heating apparatus forming the gas outlet surface can be adjusted to a temperature, at which the vapor within the gas heating apparatus condenses. It suffices if this region of the process gas distribution chamber, which can be cooled, is limited to a region that lies directly upstream of the gas outlet surface. Multiple process gas outlet zones for different starting materials may also be arranged between the two outer gas outlet zones. These multiple gas outlet zones preferably border directly on one another.

Due to the serial arrangement of multiple gas inlet elements that respectively bridge the substrate, different organic starting materials can be deposited on top of one another while the substrate is moved relative to the one or more gas outlet elements. More than three different starting materials can be respectively introduced into the process chamber with the aid of one individual linear gas inlet element, wherein the gas flow transporting the gaseous starting material is respectively flanked by two auxiliary gas curtains. The auxiliary gas is preferably nitrogen. These gas curtain flows have two functions. They insulate the central vapor flow from a thermal variation. Since the gas curtain flows are likewise heated, the gas flow transporting the starting material maintains a homogenous temperature profile. The edge regions of this central gas flow have the same temperature as the core region. Consequently, no condensation takes place within the flow path from the gas outlet zone to the substrate. The condensation only takes place once this gas flow reaches the substrate surface. The second function of the gas curtain flows is the above-described collimating function. Another advantage of the inventive design of a gas inlet element can be seen in that a cross-contamination with other gaseous starting materials is prevented. A condensation of the gaseous starting material at locations within the process chamber other than the surface of the substrate is also effectively prevented.

### BRIEF DESCRIPTION OF THE DRAWINGS

Exemplary embodiments of the invention are described in greater detail below with reference to the attached drawings. In these drawings:

FIG. 1 shows a perspective view of two linear gas inlet elements 2, 2′ that are arranged parallel to one another and cross an elongate substrate 1,

FIG. 2 shows a section through the gas inlet element along the line II-II,

FIG. 3 shows a section along the line in FIG. 2,

FIG. 4 shows a section along the line IV-IV in FIG. 2,

FIG. 5 shows a front view corresponding to the arrow V in FIG. 2,

FIG. 6 shows an illustration of a partially opened gas inlet element, and

FIG. 7 shows a second exemplary embodiment of the invention in the form of an illustration according to FIG. 3.

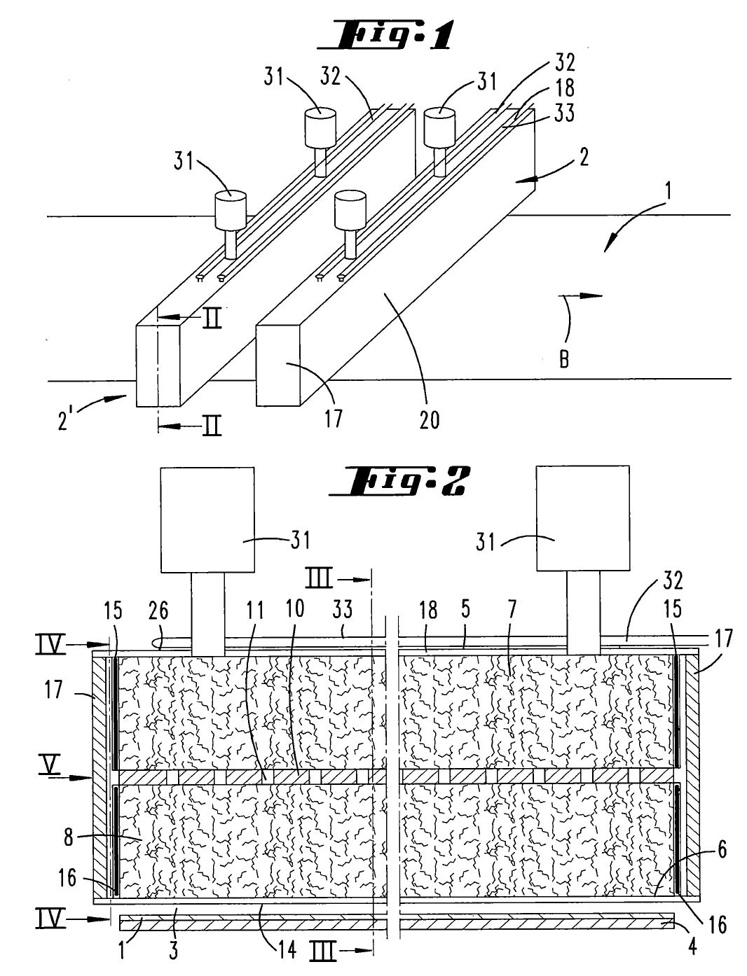

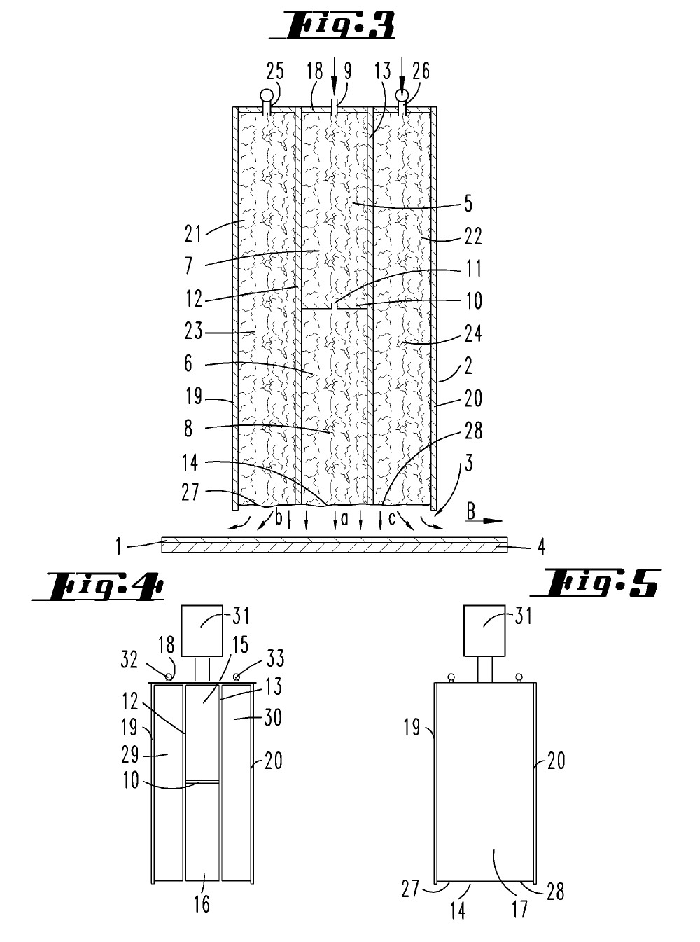

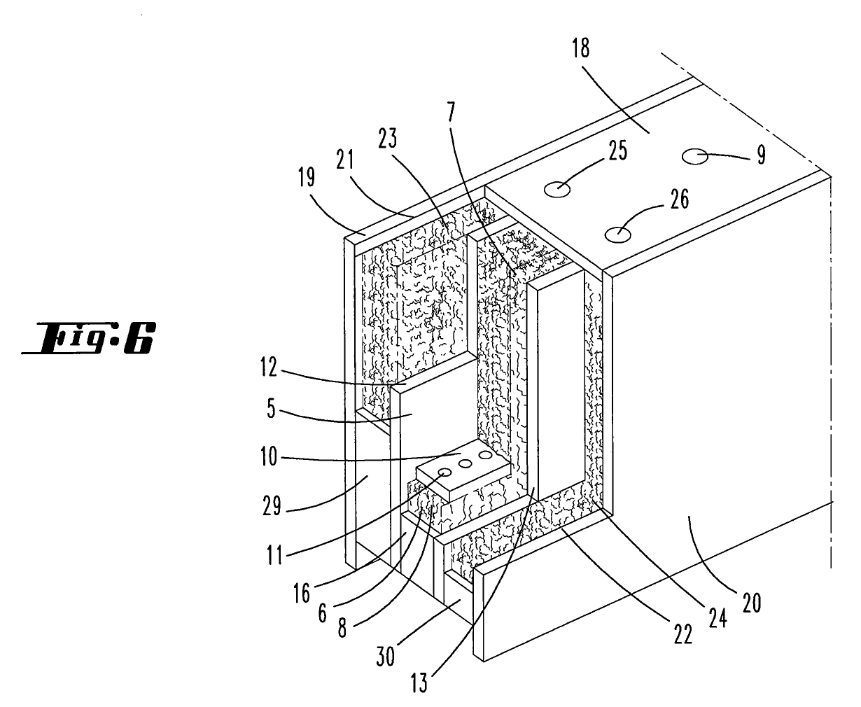

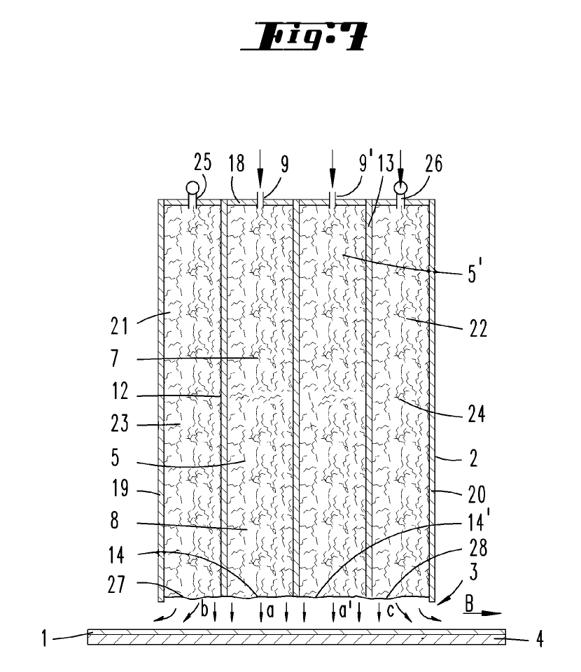

### DETAILED DESCRIPTION OF THE INVENTION

The essential elements of a PVD device for coating a substrate 1 lying on a cooled susceptor 4 with an organic material are illustrated in the drawings. In this case, two gas inlet elements 2, 2′ extend over a large-surface substrate 1 in a bridge-like fashion. The substrate 1 is moved relative to the two gas inlet elements 2, 2′ in a moving direction B, wherein said gas inlet elements extend transverse to the moving direction B. The gas inlet elements 2, 2′ are arranged parallel to one another and spaced apart from one another in the moving direction B.

The respective gas inlet element 2 or 2′ features an elongate housing with two end faces that point away from one another. The end faces are formed by the small lateral surfaces of the housing that lie on this side and on the other side of the substrate 1.

The side of the gas inlet element 2 pointing toward the surface of the substrate 1 to be coated forms three gas outlet zones 14, 27, 28 that lie linearly adjacent to one another. The gas outlet zones 14, 27, 28 extend over the entire width of the substrate 1 transverse to the moving direction B thereof. A first gas flow a, which contains a vapor of an organic starting material transported by an inert carrier gas flow, flows out of the central gas outlet zone 14. This first gas flow a is flanked by a second gas flow b and by a third gas flow c. The second gas flow b and the third gas flow c are respectively formed by a heated inert gas flow. The gas outlet zones 27, 28 for the outflow of the flanking gas flows b, c are arranged directly adjacent to the central gas outlet zone 14. The respective gas outlet zones 27, 14 and 28, 14 are only separated from one another by a thin partition wall 12, 13 consisting of an insulating material such as, for example, a ceramic material (Cogebi).

The gas outlet zones 14, 27, 28 are formed by the surfaces of electrically conductive foam bodies 23, 24, 8. The foam bodies 23, 24, 8 lie in chambers 6, 21, 22 formed by the housing of the gas inlet element 2. The open-pored foam bodies 23, 8, 24 completely occupy the gas distribution chambers 21, 6, 22 assigned thereto. The two gas distribution chambers 21, 22 assigned to the flanking second and third gas outlet zones 27, 28 are respectively defined by an outer wall 19, 20 and a partition wall 12, 13, which respectively consist of an electrically insulating material, whereas a first gas distribution chamber 6 consisting of two sections 5, 6 is defined by the two partition walls 12, 13. The entire width of the gas distribution chambers 21, 6, 22 is available as gas outlet zones 14, 27, 28.

The housing of the gas inlet element 2 has an upper wall 18 that is also made of an electrically insulating material. A gas infeed into the gas distribution chambers 5, 21, 22 takes place through this upper wall 18. An aerosol is fed to an upstream section 5 of the first gas distribution chamber, which is completely occupied by a foam body 7, through a feed line 9. The aerosol is generated in an aerosol generator 31. This aerosol generator features a reservoir for a powder or a liquid and an injector for injecting the powder or droplets of the liquid into a carrier gas flow. The solid or liquid particles of the organic starting material are fed into the foam body 7 of the upper section 5 of the gas distribution chamber with the carrier gas flow. The infeed of the aerosol takes place through the openings in the upper wall 18, which lie opposite of the gas outlet zone 14.

The upper wall 18 is provided with gas inlet openings 25, 26, through which an inert gas is respectively fed into the gas distribution chambers 21, 22 or the foam bodies 23, 24 arranged therein. The gas inlet openings 25, 26 are connected to feed lines 32, 33 for the inert gas.

The foam bodies 7, 8, 23, 24 can be heated by means of electrical energy. For this purpose, each of the respective gas distribution chambers 21, 22 and 5, 6 features electrodes 15, 16, 29, 30, which are held by a closing plate 17, on its opposite end faces. The electrodes 15, 16, 29, 30 are electrically insulated from one another by the partition walls 12, 13.

The central, first gas distribution chamber is divided into two sections 5, 6. A foam body 7, 8 is located in each of the two sections 5, 6. The sections 5, 6 lie behind one another referred to the flow direction and preferably vertically on top of one another. The section 5 on the gas inlet side forms an evaporation chamber. The foam body 7 arranged therein forms an evaporation apparatus, by means of which the aerosol fed into the section 5 on the gas inlet side through the feed line 9 is evaporated.

The section 6 on the gas outlet side is separated from the section 5 on the gas inlet side by a separating plate 10 that is made of an electrically insulating material. The separating plate 10 forms a flow restriction device because it generates a resistance to the flow. It may consist of a diffusor plate. The separating plate 10 features openings 11, through which the evaporated gaseous starting material can flow from the section 5 on the gas inlet side into the section 6 on the gas outlet side together with the carrier gas.

The foam body 8, which is located in the section 6 on the gas outlet side and forms the gas outlet opening 14, can be heated separately of the foam body 7 arranged in the section 5 on the gas inlet side. It is also conceivable to provide not-shown means for cooling this foam body 8 on the gas outlet side such that gaseous starting material flowing in through the opening 10 locally condenses. Consequently, the material flow of the starting material in the gas flow a can be varied by varying the temperature of the foam body 8 on the gas outlet side. An activation or deactivation can also be realized.

During the coating step, a gaseous organic starting material flows out of the central gas outlet opening 14 with a temperature that lies above the evaporation temperature of the starting material. The gas flows b, c on the edges, which flank the central gas flow, essentially have the same temperature as the central gas flow a such that they fulfill an insulating function. Since the gas flows b, c on the edges extend directly adjacent to the central gas flow a, they impose a linear moving direction on the central gas flow a. A divergence of the linear gas flow a, b, c flowing out of the gas inlet element 2 therefore only takes place in the outer regions of the gas flows b, c on the edges.

The electrodes 15, 16, 29, 30 may be fixed on the foam bodies 7, 8, 23, 24 with screws. The foam bodies 7, 8, 23, 24 are separated from one another and from the surroundings over the entire length of the gas inlet element 2 by means of insulating walls 12, 13, 19, 20, 18.

The aerosol contains solid or liquid particles with an average diameter in the micrometer range. The particles preferably have an essentially uniform size. The temperature of the heat-resistant foam bodies 7, 8, 23, 24 is measured by means of temperature measuring devices such as, for example, thermocouples. A temperature control takes place. Closed control loops are provided for this purpose.

The separating plate 10 is a diffusor plate with a plurality of openings 11, which particularly are uniformly spaced apart from one another, such that a homogenization of the gas flow takes place. Due to the above-described condensation of the organic starting material on the cell walls of the foam body 8 in the section 6 of the gas distribution chamber on the gas outlet side, a stabilized vapor infeed into the process chamber 3 can be ensured between the gas outlet opening 14 and the surface of the substrate 1.

The gas flows b, c on the edges, which flank the central gas flow a, prevent turbulences from forming in the region of the central gas flow a. They furthermore prevent other organic starting materials, which are fed into the process chamber by other gas inlet elements, from reaching the central gas flow a. It is therefore possible to arrange multiple gas inlet elements 2, 2′ in the same process chamber 3 behind one another referred to the moving direction B of the substrate 1 in order to transport different organic starting materials to the surface of the substrate 1, on which they form a layer due to condensation.

The aerosol can be transported from the aerosol generator 31, which may also feature an aerosol metering device, into the gas distribution chamber 5 by means of nitrogen. Nitrogen may likewise be fed into the outer gas distribution chambers 21, 22 that flank the central gas distribution chambers 5, 6. The gas flow rates are chosen such that a homogenous gas flow exits the gas outlet zones 27, 14, 28. The average gas outflow speed from the gas outlet zones 14, 27, 28 is preferably identical.

FIG. 7 shows a second exemplary embodiment of the invention in the form of an illustration according to FIG. 3. Two process gas distribution chambers 5, 5′ are provided. In this exemplary embodiment, the two process gas distribution chambers 5, 5′ are not respectively divided into two sections by a separating plate. However, it is preferably also possible to adjust the sections of the process gas distribution chambers 5, 5′ bordering on the process gas outlet zones 14, 14′ to a temperature that lies below the condensation temperature of the vapor. In this case, only the carrier gas, by means of which the aerosol stream is fed into the infeed openings 9, 9′, respectively flows out of the adjacently extending process gas outlet zones 14, 14′. However, a process gas flow a, a′ respectively flows out of the directly adjacent process gas outlet zones 14, 14′ if the entire volume of both process gas distribution chambers 5, 5′ is heated to a temperature that lies above the evaporation temperature of the organic material fed into the infeed openings 9, 9′. The two process gas distribution chambers 5, 5′ directly border on one another. They are merely separated from one another by an electrically non-conductive partition wall. The evaporation apparatuses 7 within the process gas distribution chambers 5, 5′ can be heated to different temperatures. The sections of the evaporation apparatuses, which directly border on the process gas outlet zones 14, 14′, particularly can be heated to different temperatures such that it is possible to allow process gases to flow out through both gas outlet zones 14, 14′ or only one of the two process gas outlet zones 14, 14′.

The two process gas flows a, a′ are flanked by tempering gas flows b, c, which flow out of separately heatable gas distribution chambers 21, 22.

The preceding explanations serve for elucidating all inventions that are included in this application and respectively enhance the prior art independently with at least the following combinations of characteristics, namely:

A device, which is characterized in that the gas heating apparatuses are formed by electrically conductive, open-pored solid bodies that can be heated by means of electrical energy and are arranged in the gas distribution chambers 5, 6, 5′; 21, 22, which are separated from one another by electrically insulating partition walls 12, 13, wherein at least a section of the open-pored solid body arranged in the process gas distribution chamber 5, 5′, 6 on the gas inlet side forms an evaporation apparatus 7 for a solid or liquid starting material that can be fed in through the infeed opening 9.

A device, which is characterized in that the gas heating apparatuses are formed by electrically conductive, open-pored solid bodies, particularly foam bodies 7, 8, 23, 24.

A device, which is characterized in that the foam bodies 7, 8, 23, 24 completely occupy the gas distribution chambers 5, 6, 21, 22 assigned thereto.

A device, which is characterized in that two electrodes 15, 16, 29, 30 are assigned to each gas heating apparatus 7, 8, 23, 24, wherein the electrodes 15, 16, 29, 30 are particularly arranged on the opposite end faces of the gas inlet element 2.

A device, which is characterized in that the first process gas distribution chamber 5, 6 is divided into an upstream section 5 and a downstream section 6 by means of a flow restriction device 10.

A device, which is characterized in that the flow restriction device 10 is a plate with openings 11.

A device, which is characterized in that at least two process gas distribution chambers 5, 5′, 6 are arranged adjacent to one another, wherein the second gas outlet zone 27 is arranged upstream and the third gas outlet zone 28 is arranged downstream of the at least two process gas outlet zones 14, 14′ of the process gas distribution chambers 5, 5′, 6.

A device, which is characterized in that multiple gas inlet elements 2, 2′ of essentially identical design are arranged behind one another referred to the moving direction B of the substrate 1 such that they linearly and transversely extend over the moving path of the substrate 1.

A device, which is characterized in that the gas outlet openings 14, 27, 28 are formed by the surfaces of the porous solid bodies 8, 23, 24.

All disclosed characteristics are essential to the invention (individually, but also in combination with one another). The disclosure content of the associated/attached priority documents (copy of the priority application) is hereby fully incorporated into the disclosure of this application, namely also for the purpose of integrating characteristics of these documents into claims of the present application. The characteristic features of the dependent claims characterize independent inventive enhancements of the prior art, particularly in order to submit divisional applications on the basis of these claims.

List of Reference Symbols:

| | |
|---|---|
| 1 | Substrate |
| 2 | Gas inlet element |
| 2′ | Gas inlet element |
| 3 | Process chamber |
| 4 | Susceptor |
| 5, 5′ | Process gas distribution chamber, upstream section |
| 6 | Process gas distribution chamber, downstream section |
| 7 | Evaporation apparatus, foam body |
| 8 | Foam body |
| 9, 9′ | Infeed opening, feed line |
| 10 | Flow restriction plate, separating plate |
| 11 | Opening |
| 12 | Partition wall |
| 13 | Partition wall |
| 14 | Process gas outlet zone, process gas |
| 14′ | outlet opening |
| 15 | Electrode |
| 16 | Electrode |
| 17 | Closing plate |
| 18 | Upper wall |
| 19 | Wall |
| 20 | Wall |
| 21 | Gas distribution chamber |
| 22 | Gas distribution chamber |
| 23 | Foam body |
| 24 | Foam body |
| 25 | Gas inlet opening |
| 26 | Gas inlet opening |
| 27 | Gas outlet zone |
| 28 | Gas outlet zone |
| 29 | Electrode |
| 30 | Electrode |
| 31 | Aerosol generator |
| 32 | Feed line |
| 33 | Feed line |
| B | Moving direction |
| a | Process gas flow |
| a′ | Process gas flow |
| b | Tempering gas flow |
| c | Tempering gas flow |

1. A device for depositing a layer on a substrate (1), the device comprising:
a process chamber (3); and
a first gas inlet element (2),
wherein the substrate (1) is moved across a moving path in a moving direction (B) in the process chamber (3) transverse to a direction of extent of the gas inlet element (2) during a coating process,
wherein the first gas inlet element (2) comprises:
at least one process gas distribution chamber (5, 5′, 6) with an infeed opening (9, 9′) for feeding in at least one starting material and with a-at least one process gas outlet zone (14, 14′), which extends over an entire width of the moving path of the substrate (1) and points toward the substrate (1), for the outflow of a process gas flow (a, a′) containing the starting material,
a second gas distribution chamber (21), wherein, parallel to a direction of extent of the first at least one process gas outlet zone (14, 14′), a second gas outlet zone (27) of a-the second gas distribution chamber (21) is arranged in front of the at least one process gas outlet zone (14, 14′) with respect to the moving direction (B) of the substrate (1) for the outflow of a second gas flow (b), and
a third gas distribution chamber (22), wherein, parallel to the direction of extent of the at least one process gas outlet zone (14, 14′), a third gas outlet zone (28) of a-the third gas distribution chamber (22) is arranged behind the at least one process gas outlet zone (14, 14′) with respect to the moving direction (B) of the substrate (1) for the outflow of a third gas flow (c), and wherein the second and third gas outlet zones (27, 28) are arranged directly adjacent to the at least one process gas outlet zone (14, 14′), and
gas heating apparatuses, wherein the gas heating apparatuses are formed by electrically conductive, open-pored solid bodies that are heated by means of electrical energy and are arranged in the at least one process gas distribution chamber (5, 5′, 6), the second gas distribution chamber (21) and the third gas distribution chamber (22), which are separated from one another by electrically insulating partition walls (12, 13), wherein at least a section (5) of the open-pored solid body arranged in the at least one process gas distribution chamber (5, 5′, 6) adjacent to the infeed opening (9) forms an evaporation apparatus (7) for a solid or liquid starting material that is fed in through the infeed opening (9).

2. The device of claim 1, wherein the gas heating apparatuses are formed by foam bodies (7, 8, 23, 24).

3. The device of claim 2, wherein the foam bodies (7, 8, 23, 24) completely occupy the at least one process gas distribution chamber (5, 5′, 6), the second gas distribution chamber (21) and the third gas distribution chamber (22).

4. The device of claim 1, further comprising:
a plurality of electrodes (15, 16, 29, 30), wherein two of the electrodes (15, 16, 29, 30) are assigned to each of the gas heating apparatuses (7, 8, 23, 24).

5. The device of claim 4, wherein the at least one process gas distribution chamber (5, 5′, 6) comprises a first process gas distribution chamber (5, 6), wherein the first process gas distribution chamber (5, 6) is divided into an upstream section (5) and a downstream section (6) by means of a flow restriction device (10).

6. The device of claim 5, wherein the flow restriction device (10) comprises a plate with openings (11).

7. The device of claim 1,
wherein the at least one process gas distribution chamber (5, 5′,6) comprises a first process gas distribution chamber (5) and a second process gas distribution chamber (5′) which are arranged adjacent to one another,
wherein the at least one process gas outlet zone (14, 14′) comprises a first process gas outlet zone (14) and a second process gas outlet zone (14′), and
wherein the second gas outlet zone (22) (27) is arranged upstream and the third gas outlet zone (28) is arranged downstream of the first and second process gas outlet zones (14, 14′).

8. The device of claim 1, further comprising:
a second gas inlet element (2′), wherein the first gas inlet element (2) and the second gas inlet element (2′) are arranged behind one another with respect to the moving direction (B) of the substrate (1) such that the first gas inlet element (2) and the second gas inlet element (2′) linearly and transversely extend over the moving path of the substrate (1).

9. The device of claim 1, wherein gas outlet openings within the at least one process gas outlet zone (14, 14′), the first gas outlet zone (27) and the second gas outlet zone (28) are formed by surfaces of the open-pored solid bodies (8, 23, 24).

10. (canceled)

11. The device of claim 4, wherein the electrodes (15, 16, 29, 30) are arranged on opposite end faces of the first gas inlet element (2).

12. The device of claim 8, wherein the first and second gas inlet elements (2, 2′) are substantially identical to one another.
